(19) United States
(12) Patent Application Publication
(10) Pub. No.: US 2011/0096862 A1
(43) Pub. Date: Apr. 28, 2011

(54) RADIO COMMUNICATION APPARATUS, RADIO COMMUNICATION SYSTEM, AND RADIO COMMUNICATION METHOD

(75) Inventors: Kenichi Kuri, Kanagawa (JP); Akihiko Nishio, Kanagawa (JP); Seigo Nakao, Kanagawa (JP)

(73) Assignee: PANASONIC CORPORATION, Osaka (JP)

(21) Appl. No.: 12/672,576

(22) PCT Filed: Jul. 14, 2008
(86) PCT No.: PCT/JP2008/001889

§ 371 Date: Feb. 8, 2010

(30) Foreign Application Priority Data
Aug. 9, 2007 (JP) 2007-208128

(51) Int. Cl. H04L 27/00; H03K 9/00

(52) U.S. Cl. 375/295; 375/316

(57) ABSTRACT

Even when a CCFI error has arisen, there is prevented occurrence of a packet error, which would otherwise be caused during the first receiving operation for reasons of erroneous storage of data into a buffer, and data are prevented from being synthesized while deviated during retransmission. A transmission Circular Buffer sequentially reads encode word data to be transmitted in reverse order from end to top like D_{—}12, D_{—}11, D_{—}1. After the data have been modulated by a modulator, a multiplexer allocates modulated data symbols D_{—}12 to D_{—}1 to OFDM symbols from the third OFDM symbol #3 subsequent to a control channel CCH in accordance with a CCFI value (=2). After demodulating received data symbols, a receiving side rearranges the demodulated information from its end to top in reverse order from a predetermined data start point, and stores the thus-rearranged information in a receiving Circular Buffer. As a result, there is avoided receiving error, which would otherwise be caused by gap of data stored in the receiving Circular Buffer and loss of the first data.

### TECHNICAL FIELD

The present invention relates to a radio communication apparatus, a radio communication system, and a radio communication method by means of which data transmission is performed by use of OFDM (Orthogonal Frequency Division Multiplexing).

### BACKGROUND ART

Third-generation mobile communication service is started, and multimedia communication, such as data communication and video communication, has recently become very brisk. Against the background, the size of data transmitted by communication will become increasingly greater in future, and a demand for an increase in data rate will rise.

According to 3GPP-LTE (3rd Generation Partnership Project Long Term Evolution), standardization activities are actively conducted with a view toward realizing 100-Mbps high-speed transmission. A scheme based on OFDM is conceivable as the most promising communication scheme for accomplishing an objective.

In order to improve a frequency utilization factor, HARQ (Hybrid Automatic Repeat Request) utilizing an error correct code and retransmission control in combination has been studied. In relation to a 3GPP-LTE HARQ system, CBRM (Circular Buffer Based Rate Matching) has been examined in order to simplify the definition of retransmission data, such as a redundancy version (hereinafter abbreviated as “RV”) (see Non-Patent Document 1). CBRM is a rate matching technique for reading in a circulatory manner a turbo encode word accumulated in a Circular Buffer, which is of circulatory read type, from an arbitrary start point in order of buffer address, thereby defining an RV.

Non-Patent Document 1: R1-072604, “Way forward on HARQ rate matching for LTE,” Ericsson, et al., 3GPP TSG-RAN WG1 RAN1#49 contribution, 2007/05

### DISCLOSURE OF THE INVENTION

### Problem that the Invention is to Solve

FIG. 11 shows an exemplary allocation configuration of data achieved at a transmission station and an exemplary allocation configuration of data achieved at a receiving station when Circular Buffers are used. In FIG. 11, a transmission station NB (Node-B) designates 3GPP-LTE radio communication base station equipment at a transmission end, and a receiving station P-UE (Persistent-User Equipment) designates 3GPP-LTE radio communication mobile station equipment at a receiving end. The Persistent-User Equipment corresponds to a user terminal to which Persistent-scheduling is applied. Persistent-scheduling corresponds to scheduling intended for reducing control information pertaining to scheduling by determining a scheduling pattern beforehand between the transmission station and the receiving station. The configuration of a transmission Circular Buffer in the transmission station NB compliant with the receiving station P-UE and the configuration of a receiving Circular Buffer in the receiving station P-UE are provided.

The receiving station P-UE receives data after having made reference to a CCFI (Control Channel Format Indicator) at a TTI (Transmission Time Interval) during which data allocation is carried out. Here, the term TTI designates a time unit (e.g., 1 ms) at which scheduling is performed. The term CCFI means information for reporting an OFDM symbol number to which control information is allocated at a TTI. The example of FIG. 11 shows a situation in which the data transmitted by means of CCFI=2 by the transmission station NB are erroneously received by the receiving station P-UE as having been transmitted by CCFI=3. Control information is shown by a CCH (Control Channel) that is control information about the scheduled receiving station P-UE. A CCFI is allocated to any of subcarriers of an OFDM symbol #1 in a transmission frequency band and is not subjected to error detection encoding. Therefore, the probability is high that a CCFI error will arise, which may cause erroneous interpretation.

Since the receiving station P-UE performs receiving by means of CCFI=3 in this case, data D_1 positioned at the third OFDM symbol #3 in the TTI are lost during receiving operation. Further, the receiving station P-UE determines a receiving start point as data D_2 pertaining to the fourth OFDM symbol #4 and stores the data into the receiving Circular Buffer. Therefore, the data D_2 are first arranged in the receiving Circular Buffer where data D_1 should originally be arranged first, whereby data are stored in the receiving Circular Buffer while being wholly deviated. The loss of first data and the gap of a storage position in the buffer result in occurrence of a packet error during first receiving operation. Further, data are synthesized even at the time of retransmission while the storage position in the buffer remains deviated; therefore, there still remains a problem of an inability to solve the packet error.

The present invention has been conceived in view of the circumstance and aims at providing a radio communication apparatus, a radio communication system, and a radio communication method that can prevent occurrence of a packet error, which would otherwise arise during the first receiving operation because of erroneous storage of data in a buffer even when a CCFI error has arisen and that can prevent data from being synthesized while deviated during retransmission.

### Means for Solving the Problem

A first aspect of the present invention provides a radio communication apparatus that serves as a transmission station for transmitting data using OFDM (Orthogonal Frequency Division Multiplexing) to a receiving station to which Persistent-scheduling is applied, the radio communication apparatus comprising: a Circular Buffer for storing data to be transmitted to the receiving station; and a transmission data processor that processes data to be transmitted to the receiving station to which Persistent-scheduling is applied, in reverse order in either processing for reading data from the Circular Buffer or processing for allocating modulated data symbols to OFDM symbols.

Therefore, even when a receiving station to which Persistent-scheduling is applied has caused a CCFI error, it is possible to prevent occurrence of a packet error, which would otherwise arise during the first receiving operation because of erroneous storage of data in a buffer, and to prevent data from being synthesized while deviated during retransmission.

A second aspect of the present invention includes a radio communication apparatus according to the first aspect, wherein the transmission data processor reads in reverse order data to be transmitted from an end of the data during processing for reading data from the Circular Buffer.

A third aspect of the present invention includes a radio communication apparatus according to the first aspect, wherein the transmission data processor allocates data in reverse order from an end of OFDM symbols during processing for allocating modulated data symbols to OFDM symbols.

A fourth aspect of the present invention includes a radio communication apparatus according to the first aspect, wherein, when one Transport-block to be transmitted to the receiving station contains a plurality of Code-blocks, the transmission data processor uniformly allocates all sets of Code-blocks data to respective OFDM symbols.

Therefore, even when a receiving station to which Persistent-scheduling is applied has caused a CCFI error, it is possible to prevent occurrence of a packet error, which would otherwise be caused by subsequent Code-blocks as a result of erroneous storage of data, and it is possible to prevent data from being synthesized while deviated during retransmission.

A fifth aspect of the present invention includes a radio communication apparatus according to the fourth aspect, wherein the transmission data processor allocates all sets of Code-blocks data to respective OFDM symbols so as to become uniform in time domain.

A sixth aspect of the present invention includes a radio communication apparatus according to the fourth aspect, wherein the transmission data processor allocates all sets of Code-blocks data to respective OFDM symbols so as to become uniform in a frequency domain.

A seventh aspect of the present invention includes a radio communication apparatus according to the fourth aspect, wherein the transmission data processor allocates all sets of Code-blocks data so as to become uniform solely to OFDM symbols to which a control channel is possibly allocated.

An eighth aspect of the present invention includes a radio communication apparatus according to the first aspect, wherein, when a first receiving station to which Dynamic-scheduling is applied and a second receiving station to which Persistent-scheduling is applied are multiplexed in a distributed manner as receiving stations that are objects of transmission from the transmission station, the transmission data processor allocates data to be transmitted to the second receiving station to which Persistent-scheduling is applied, in reverse order from an end of OFDM symbols in a transmission period.

Therefore, it is possible to avoid intermittent allocation of data in respective receiving stations when data are allocated to a plurality of receiving stations. In this case, it is possible to make an allocation area of a first receiving station to which Dynamic-scheduling is applied temporally continuously. Since continuous receiving is possible without regard to a CCFI value, receiving operation becomes simple.

A ninth aspect of the present invention includes a radio communication apparatus according to the first aspect, further comprising a control information processor that incorporates a CCFI (Control Channel Format Indicator) information accepted during previous receiving operation, into control information to be notified when data are retransmitted to the receiving station to which Persistent-scheduling is applied.

Therefore, even when a receiving station to which Persistent-scheduling is applied has caused a CCFI error, it is possible to prevent excessive receipt of data. Further, since data that are uncertain during first receiving operation are synthesized from retransmitted control information, to thus decode the data, an encoding gain is acquired.

A tenth aspect of the present invention provides a radio communication apparatus that serves as a receiving station to which Persistent-scheduling is applied and that performs data transmission with a transmission station by use of OFDM (Orthogonal Frequency Division Multiplexing), the radio communication apparatus comprising: a Circular Buffer for storing data transmitted by the transmission station; and a received data processor that, when received from the transmission station data allocated to OFDM symbols in reverse order, rearranges the data in reverse order and stores the rearranged data in predetermined data storage positions during processing for storing data into the Circular Buffer.

An eleventh aspect of the present invention includes a radio communication apparatus according to the tenth aspect, wherein, when one Transport-block to be transmitted by the transmission station contains a plurality of Code-blocks, the received data processor rearranges and stores inversely-allocated data on a per-Code-block basis in a reverse order such that all sets of Code-blocks data become uniform with respect to respective OFDM symbols.

A twelfth aspect of the present invention includes a radio communication apparatus according to the tenth aspect, wherein, when another receiving station to which Dynamic-scheduling is applied and the own receiving station to which Persistent-scheduling is applied are multiplexed in a distributed manner as receiving stations that are objects of transmission from a transmission station, the received data processor rearranges in reverse order into original positions data allocated in reverse order from an end of OFDM symbols of the own receiving station and stores the rearranged data.

A thirteenth aspect of the present invention provides a radio communication system for transmitting data using OFDM (Orthogonal Frequency Division Multiplexing) between a transmission station and a receiving station to which Persistent-scheduling is applied, the radio communication system comprising: a first radio communication apparatus that serves as a transmission station having: a Circular Buffer for storing data to be transmitted to the receiving station; and a transmission data processor that processes data to be transmitted to the receiving station to which Persistent-scheduling is applied, in reverse order in either processing for reading data from the Circular Buffer or processing for allocating modulated data symbols to OFDM symbols; and a second radio communication apparatus that serves as a receiving station to which Persistent-scheduling is applied having: a Circular Buffer for storing data transmitted by the transmission station; and a received data processor that, when received data allocated in reverse order from the transmission station, stores the data in reverse order in predetermined data storage positions during processing for storing data into the Circular Buffer.

A fourteenth aspect of the present invention provides a radio communication method for a radio communication apparatus that serves as a transmission station for transmitting data using OFDM (Orthogonal Frequency Division Multiplexing) to a receiving station to which Persistent-scheduling is applied, the method comprising: a transmission data processing step of processing data to be transmitted to the receiving station to which Persistent-scheduling is applied, in reverse order in either processing for reading data from a Circular Buffer that stores data to be transmitted to the receiving station or processing for allocating modulated data symbols to OFDM symbols.

A fifteenth aspect of the present invention provides a radio communication method for a radio communication apparatus that serves as a receiving station to which Persistent-scheduling is applied and that performs data transmission with a transmission station by use of OFDM (Orthogonal Frequency Division Multiplexing), the method comprising: a received data processing step of, when received data allocated in reverse order from the transmission station, storing the data in reverse order in predetermined data storage positions during processing for storing data into a Circular Buffer that stores data received from the transmission station.

### ADVANTAGEOUS EFFECT OF THE INVENTION

The present invention can provide a radio communication apparatus, a radio communication system, and a radio communication method that can prevent occurrence of a packet error, which would otherwise arise during the first receiving operation because of erroneous storage of data in a buffer even when a CCFI error has arisen and that can prevent data from being synthesized while deviated during retransmission.

### BRIEF DESCRIPTIONS OF THE DRAWINGS

FIG. 1 shows a block diagram of a transmission station of embodiments of the present invention.

FIG. 2 shows exemplary data processing and an exemplary allocation configuration of data in the transmission station of the first embodiment.

FIG. 3 shows a block diagram of a receiving station of embodiments of the present invention.

FIG. 4 shows exemplary data processing and an exemplary allocation configuration of data in the receiving station of the first embodiment.

FIG. 5 shows exemplary data processing and an exemplary allocation configuration of data of a second embodiment.

FIG. 6 shows exemplary data processing and an exemplary allocation configuration of data of a third embodiment.

FIG. 7 shows exemplary data processing and an exemplary allocation configuration of data of a first modification of the embodiment.

FIG. 8 shows exemplary data processing and an exemplary allocation configuration of data of a second modification.

FIG. 9 shows exemplary data processing and an exemplary allocation configuration of data of a third modification of the embodiment.

FIG. 10 shows exemplary data processing and an exemplary allocation configuration of data of a fourth modification of the embodiment.

FIG. 11 shows an exemplary allocation configuration of data in both a transmission station and a receiving station achieved when a Circular Buffer is used.

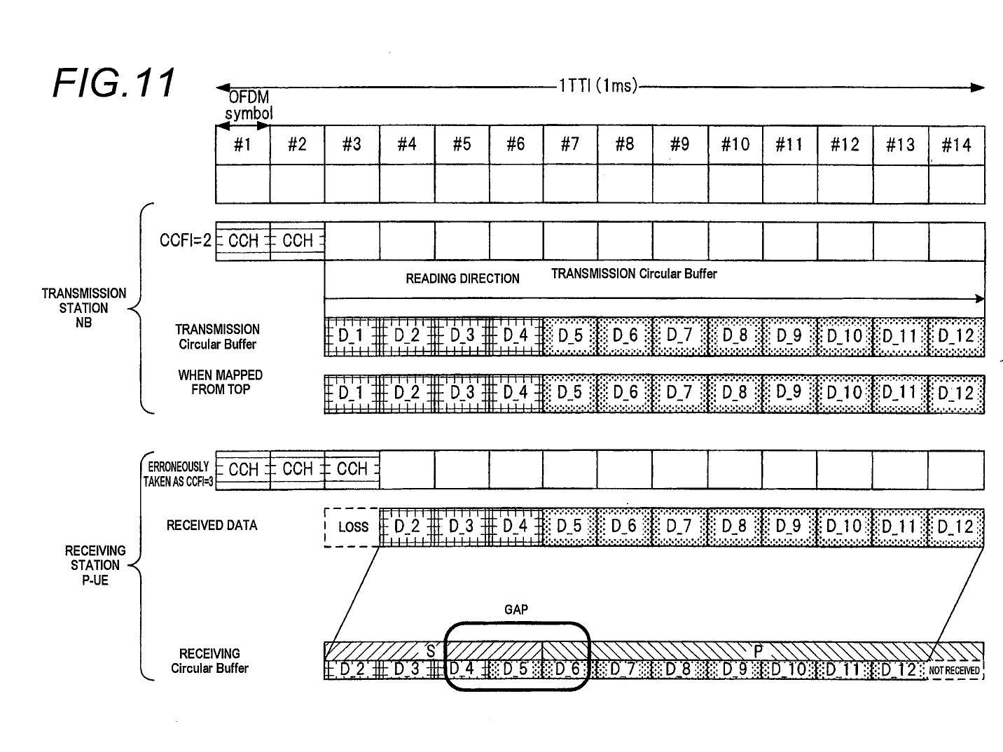

### DESCRIPTIONS OF THE REFERENCE NUMERALS AND SYMBOLS

100 TRANSMISSION STATION
101 CRC SECTION
102 ENCODER
103 TRANSMISSION Circular Buffer
104 MODULATOR
105 MULTIPLEXER
106 IFFT SECTION
107 TRANSMISSION RF SECTION
108 ANTENNA
109 RECEIVING RF SECTION
110 DEMODULATOR
111 DECODER
112 CONTROLLER
300 RECEIVING STATION
301 ANTENNA
302 RECEIVING RF SECTION
303 FFT SECTION
304 SEPARATOR
305 DEMODULATOR
306 RECEIVING Circular Buffer
307 DECODER
308 ERROR DETECTIONS SECTION
309 CHANNEL QUALITY ESTIMATOR
310 CONTROL SIGNAL GENERATOR
311 ENCODER
312 MODULATOR
313 TRANSMISSION RF SECTION

### BEST MODES FOR IMPLEMENTING THE INVENTION

By way of examples of a radio communication system, a radio communication apparatus, and a retransmission control method of the present invention, present embodiments show example configurations achieved when communication is performed by means of a radio transmission scheme using OFDM. The following descriptions of the embodiments are based on the assumption that an FDD (Frequency Division Duplex) system will be used. The present invention can also be practiced by use of a TDD (Time Division Duplex) system. Note that an end that transmits data is taken as a transmission station, whilst an end that receives data is taken as a receiving station. The following embodiments are mere examples for illustration purposes, and the present invention is not limited to these embodiments.

### First Embodiment

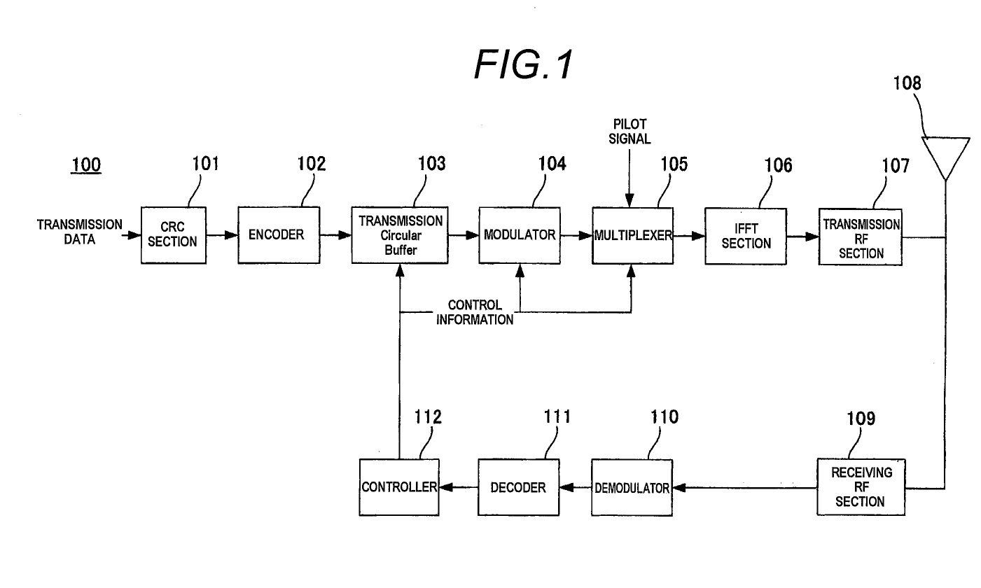

FIG. 1 shows a block configuration of a transmission station of an embodiment of the present invention. A radio communication apparatus serving as a transmission station 100 includes a CRC section 101, an encoder 102, a transmission Circular Buffer 103, a modulator 104, a multiplexer 105, an IFFT section 106, a transmission RF section 107, an antenna section 108, a receiving RF section 109, a demodulator 110, a decoder 111, and a controller 112. The embodiment illustrates; for instance, a case where, when communication is established between a radio communication base station apparatus and a radio communication mobile station apparatus in a cellular system, a radio communication base station apparatus NB (Node-B) acts as a transmission station on the transmission end and where a radio communication mobile station apparatus UE (User Equipment) acts as a receiving station on the receiving end. The receiving station is assumed to be Persistent-User Equipment (hereinafter described as “Persistent-UE”) to which Persistent scheduling is applied and also presumed to perform operation for recognizing, by reference to a CCFI, an OFDM symbol number to which control information (control channels) is allocated at a TTI serving as a transmission interval, to thus specify a data symbol.

The CRC section 101 subjects input transmission data to error detection encoding (Cyclic Redundancy Check) and outputs CRC-processed data to the encoder 102. The encoder 102 subjects the CRC-processed data to turbo encoding at a mother encoding rate (e.g., a coding rate R=1/3) and outputs a derived encode word (encoded data) to the transmission Circular Buffer 103.

The transmission Circular Buffer 103 has a memory making up a buffer of circulatory read type that stores and preserves transmission data. In accordance with the size of transmission data, a coding rate, an RV parameter, a UE attribute (an attribute of a user equipment at a receiving end) input by the controller 112, the transmission Circular Buffer 103 reads encode word data to be transmitted from stored data and outputs the thus-read data to the modulator 104. In relation to the UE attribute, when a UE attribute of a receiving station that is an allocation UE is Dynamic-User Equipment (hereinafter described as “Dynamic-UE”) to which Dynamic scheduling is applied, encode word data read from a predetermined data start point in a forward order are output to the modulator 104. In the present embodiment, a start point designated by a previously-notified RV parameter is used as a data start point indicating a location where transmission data are stored. However, the data start point is not limited to this start point.

In the meantime, a UE attribute of a receiving station that is an allocation UE is a Persistent-UE to which Persistent scheduling is applied, encode word data read in a reverse order from the end are output to the modulator 104, in an area which extends from a starting point indicated by an RV parameter and is equal in size to transmission data; namely, an area which extends from the starting point to an address spaced by an amount corresponding to the size of transmission data. In the present embodiment, descriptions are primarily given to a case where a receiving station is a Persistent-UE, reading processing of the transmission Circular Buffer 103 performed in this case will later be described in detail.

The modulator 104 modulates the encode word data in sequence in which encode word data are input by the transmission Circular Buffer 103, by means of a modulation multivalued number input by the controller 112, to thus generate a data symbol and output the data symbol to the multiplexer 105.

The multiplexer 105 allocates a data symbol input by the modulator 104 to a frequency subcarrier corresponding to an allocation RB (Resource Block) number input by the controller 112. In accordance with a CCFI value input by the controller 112, the multiplexer 105 determines a number of an OFDM symbol from which allocation of a data symbol to an OFDM symbol is commenced. Further, the multiplexer 105 multiplexes a data symbol, control information input by the controller 112, and a pilot signal (a reference signal). Details of processing for allocating data symbols to OFDM symbols will later be described along with read processing of the transmission Circular Buffer.

The IFFT section 106 subjects to IFFT the information input by the multiplexer 105, thereby generating an OFDM symbol that is a multicarrier signal. The transmission RF section 107 converts a baseband signal into an RF signal through frequency conversion and transmits a transmission signal of the RF signal to a receiving station by way of the antenna 108.

The receiving RF section 109 receives the control signal transmitted from the receiving station by way of the antenna 108 and converts a received signal of the RF signal into a baseband signal through frequency conversion. Control signals received from the receiving station include a CQI (Channel Quality Indicator) representing receiving quality, ACK (Acknowledgement) and NACK (Negative Acknowledgement) signal showing that receiving is successful and unsuccessful respectively, and others.

The demodulator 110 demodulates the control signal (a CQI, an ACK signal, or a NACK signal) and outputs a demodulated signal to the decoder 111. The decoder 111 decodes the demodulated control signal (the CQI, the ACK signal, or the NACK signal) and outputs a decoded signal to the controller 112.

The controller 112 controls a coding rate, a modulation multivalued number, an allocation RB number, a CCFI value, and retransmission operation in accordance with the control signal (the CQI, the ACK signal, and the NACK signal) that has originated from each of receiving stations and is input by way of the decoder 111. The controller 112 outputs generated information about a coding rate to the transmission Circular Buffer 103; outputs a modulation multivalued number to the modulator 104; and outputs an allocation RB number, a CCFI value, and control information to the multiplexer 105. The CQI reported by the receiving station may be an average SINR (Signal-to-Interference plus Noise Power Ratio), an average SIR (Signal-to-Interference Ratio), or an MCS (Modulation and Coding Scheme) parameter. In the configuration of the transmission station, the transmission Circular Buffer 103, the multiplexer 105, and the controller 112 implement functions of a transmission data processor, and the controller 112 implements a function of a control information processor.

Details of principal processing operation of the transmission station of the first embodiment are now described. Two points; namely, read processing of the transmission Circular Buffer 103 and processing of the multiplexer 105 for allocating a data symbol to an OFDM symbol, will be described in detail.

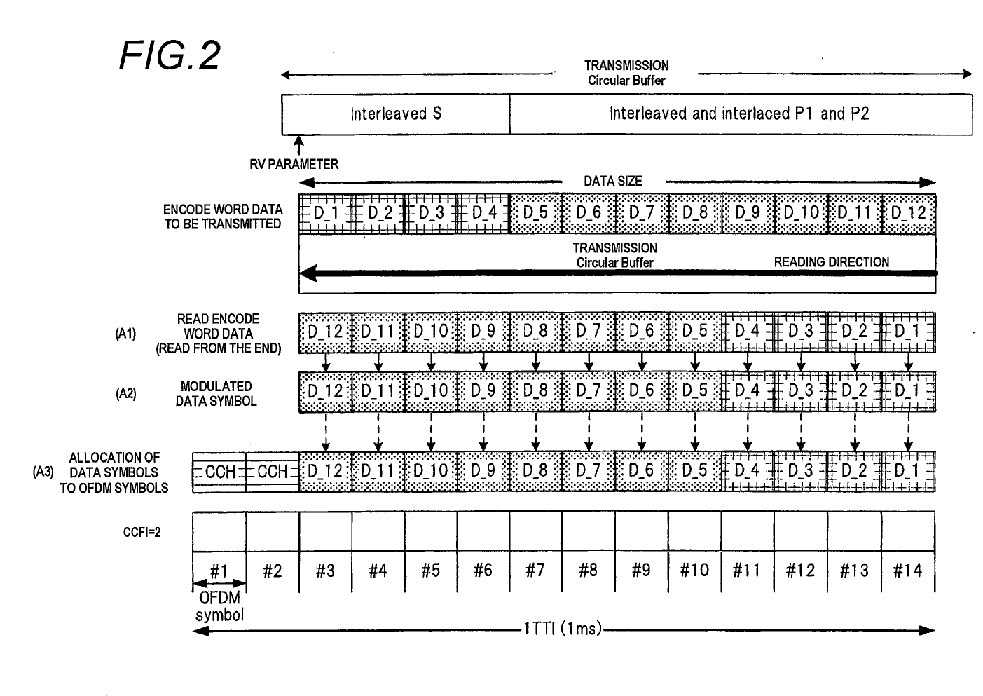

FIG. 2 shows exemplary data processing and an exemplary data allocation configuration of the transmission station of the first embodiment. FIG. 2 shows, as an exemplary allocation of a data channel of the Persistent-UE, a state of processing for reading a data channel of the Persistent-UE from the transmission Circular Buffer, modulating the channel, and allocating the modulated channel to a corresponding OFDM symbol. Explanations are herein provided for the case of CCFI=2. Processing procedures involve three stages (A1) to (A3) provided below and correspond to (A1) to (A3) shown in FIG. 2.

(A1) Read processing of the transmission Circular Buffer

In accordance with the RV parameter and the size of transmission data provided by the controller 112, the transmission Circular Buffer 103 specifies encode word data to be transmitted. Encode word data to be transmitted are herein assumed to be D_1 to D_12. Among the sets of encode word data D_1 to D_12, D_1 to D_4 correspond to systematic bits (Interleaved S in a top row of FIG. 2) of an encode word, and D_5 to D_12 correspond to parity bits (Interleaved and interlaced P1 and P2 in the top row of FIG. 2) of the encode word.

Specified encode word data are sequentially read in a reverse order from the end to the top, e.g., D_12, D_11, D_1, and the thus-read data are output to the modulator 104.

(A2) Modulation Processing

The modulator 104 modulates the encode word data D_12 to D_1 in a sequence in which the data have been input by the transmission Circular Buffer 103 by means of a modulation multivalued number input by the controller 112, to thus generate a data symbol, and outputs the symbol to the multiplexer 105.

(A3) Processing for allocating a data symbol to an OFDM symbol

In accordance with the CCFI value (=2) input by the controller 112, the multiplexer 105 allocates the data symbols D_12 to D_1 input by the modulator 104 to subcarriers of an allocation RB number in sequence from the third OFDM symbol #3. In the embodiment shown in FIG. 2, D_12 is allocated to the third OFDM symbol #3; D_11 is allocated to the fourth OFDM symbol #4; and the data symbols D_10 to D_1 are likewise allocated sequentially to the fifth to fourteenth OFDM symbols D_5 to D_14. In the present embodiment, the OFDM symbols include the fourteen symbols #1 to #14 in one TTI (one transfer interval).

In relation to the OFDM symbols, control channels CCH are allocated to the first and second OFDM symbols #1 and #2 through foregoing processing, and data symbols D_12 to D_1 are sequentially allocated to the third to fourteenth OFDM symbols #3 to #14. Specifically, the data symbols, which have been read from the transmission Circular Buffer and modulated, are sequentially allocated to OFDM symbols subsequent to the control channels CCH in an order opposite to that in which the encode word data are stored in the original transmission Circular Buffer.

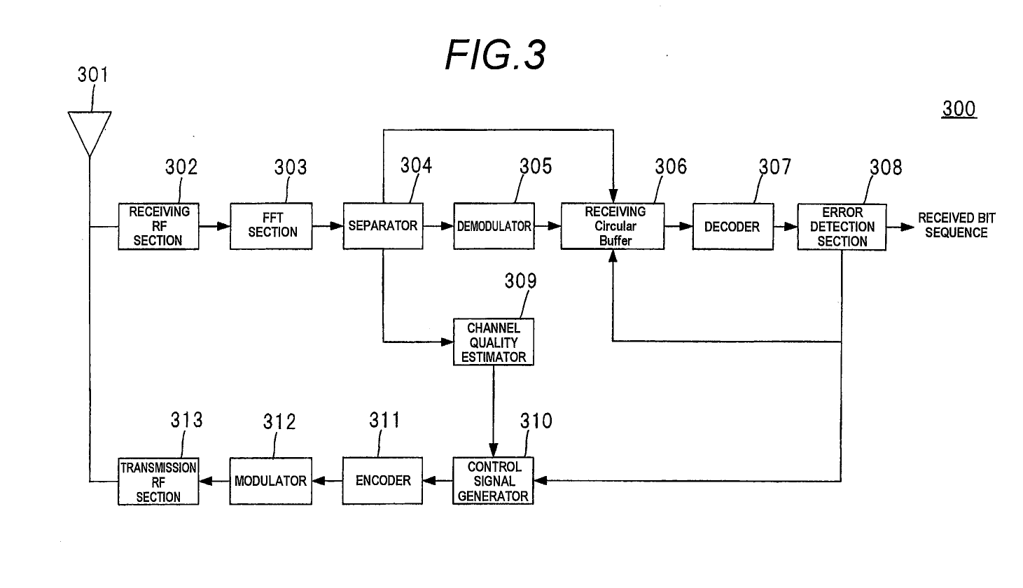

FIG. 3 shows a block configuration of the receiving station of the embodiment. A radio communication apparatus serving as a receiving station 300 includes an antenna 301, a receiving RF section 302, an FFT section 303, a separator 304, a demodulator 305, a receiving Circular Buffer 306, a decoder 307, an error detection section 308, a channel quality estimator 309, a control signal generator 310, a encoder 311, a modulator 312, and a transmission RF section 313.

The receiving RF section 302 receives a signal transmitted from a transmission station by way of the antenna 301 and converts a received signal of an RF signal into a baseband signal through frequency conversion. The FFT section 303 subjects a received OFDM symbol to FFT, to thus convert the baseband signal to a signal in a frequency domain and outputs a received data signal to the separator 304.

The separator 304 separates the received data signal into data symbols and control information (an allocation RB number, a coding rate, a modulation multivalued numeral, an RV parameter, a CCFI value, and a UE attribute); outputs data symbols of frequency subcarriers corresponding to the allocation RB number to the demodulator 305; outputs the control information (a modulation multivalued number) to the demodulator 305; and outputs control information (a coding rate, an RV parameter, and a UE attribute) to the receiving Circular Buffer 306. The separator 304 outputs a receiving pilot signal to the channel quality estimator 309. At this time, in accordance with a CCFI value, the separator 304 specifies a number of an OFDM symbol from which allocation of a data symbol to an OFDM symbol is commenced; and outputs only the data symbol allocated to the OFDM symbol corresponding to the data to the demodulator 305.

The demodulator 305 demodulates the data symbol input by the separator 304 in accordance with a modulation multivalued number reported by means of control information. Demodulated information (likelihood information acquired from the demodulated data symbols) is output to the receiving Circular Buffer 306.

The receiving Circular Buffer 306 includes a memory making up a buffer of circulatory read type that stores and keeps received data. In accordance with control information (a coding rate, an RV parameter, and a UE attribute) input by the separator 304, the receiving Circular Buffer 306 sequentially stores the information demodulated by the demodulator 305. Further, the receiving Circular Buffer 306 reads the stored demodulation information and outputs the thus-read information to the decoder 307. In relation to the UE attribute, when a UE attribute of a receiving station that is an allocation UE corresponds to a Dynamic-UE to which Dynamic scheduling is applied, information that is demodulated in the same forward order as that in which the OFDM symbols received from a predetermined data start point are demodulated is stored in the receiving Circular Buffer 306. In the present embodiment, for instance, a starting point indicated by a previously-notified RV parameter is used as a data starting point showing the location where received data are stored. However, the data starting point is not limited to this starting point.

Meanwhile, when the UE attribute of the receiving station that is an allocation UE corresponds to a Persistent-UE to which Persistent scheduling is applied, information demodulated in an order reverse to the order in which the received OFDM symbols are arranged is stored in the receiving circular Buffer 306, in an area which extends from a starting point indicated by an RV parameter and is equal in size to received data; namely, an area which extends from the starting point to an address spaced by an amount corresponding to the size of received data.

Only when an ACK signal output from the error detection section 308 is input, the receiving Circular Buffer 306 discards the received data that have already been stored. In the present embodiment, explanations are primarily given to a case where the receiving station is a Persistent-UE. Storage processing of the receiving Circular Buffer 306 performed in this case will be described later.

The decoder 307 subjects the data symbol input by the receiving Circular Buffer 306 to error correction decoding, to thus generate a decoded bit sequence. The decoded bit sequence is output to the error detection section 308. The error detection section 308 subjects the decoded bit sequence input by the decoder 307 to error detection decoding (CRC). When a result of error detection shows that the decoded bits include an error, a NACK signal is generated as a response signal. In contrast, when the decoded bits include no errors, an ACK signal is generated as a response signal. The thus-generated response signal is output to the control signal generator 310. Further, when the decoded bit sequence includes no errors, the error detection section 308 outputs the decoded bit sequence as a received bit sequence.

The channel quality estimator 309 estimates channel quality (e.g., SINR) from a received pilot signal. An estimated SINR value is output to the control signal generator 310. The control signal generator 310 generates a frame for use with feedback information from a CQI based on the estimated SINR value, or the like, input by the channel quality estimator 309 and the ACK/NACK signal input by the error detection section 308; and outputs the frame to the encoder 311.

The encoder 311 subjects the feedback information input by the control signal generator 310 to encoding. The modulator 312 modulates the encoded feedback information and outputs modulated information to the transmission RF section 313. The transmission RF section 313 converts the encoded, modulated baseband signal into an RF signal through frequency conversion and transmits a transmission signal of the RF signal to the transmission station by way of the antenna 301. In the configuration of the receiving station mentioned above, the receiving Circular Buffer 306 implements a function of the received data processor.

Details of principal processing operation of the receiving station of the first embodiment are now described. Processing for storing received data into the receiving Circular Buffer 306 will now be described in detail.

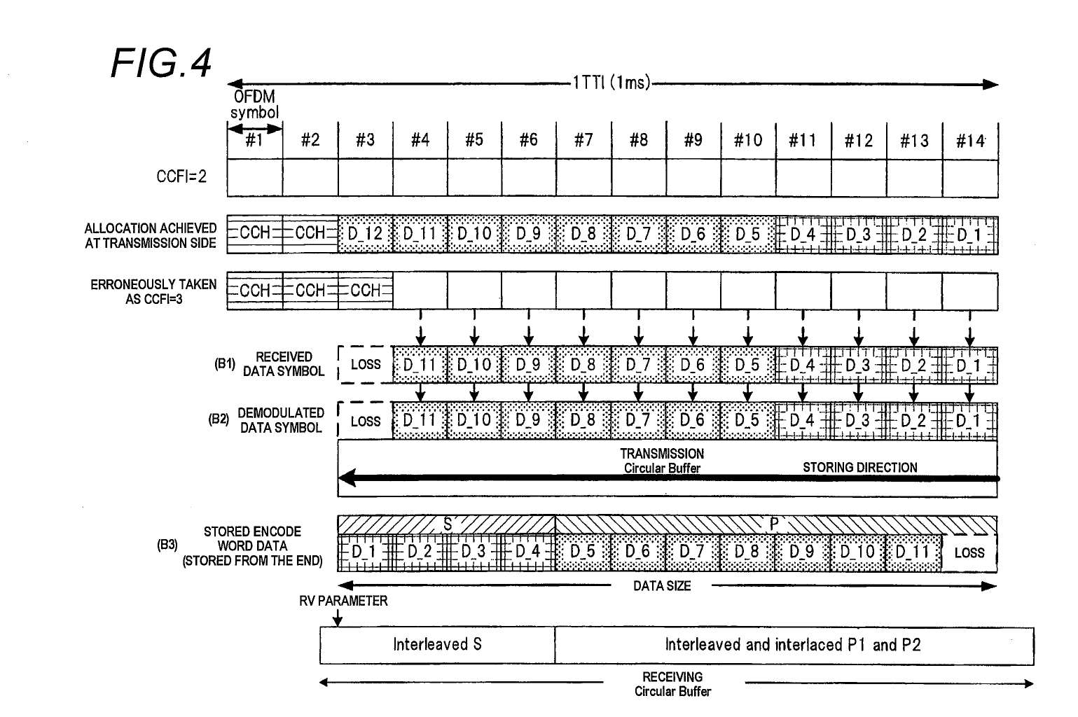

FIG. 4 shows exemplary data processing and an exemplary data allocation configuration of the receiving station of the first embodiment. FIG. 4 shows, as an exemplary allocation of a data channel of the Persistent-UE, a state of processing for specifying a received data symbol included in a data channel of a Persistent-UE and storing the symbol into the receiving Circular Buffer by way of a demodulation process. Explanations are herein provided for a case where the information transmitted by the transmission station by means of CCFI=2 is erroneously received as CCFI=3 by the receiving station. Since the CCFI is not subjected to error detection encoding, the probability is high that a CCFI error will arise, thereby causing erroneous recognition. Processing procedures involve three stages (B1) to (B3) provided below and correspond to (B1) to (B3) shown in FIG. 4.

(B1) Processing for specifying a received data symbol from an OFDM symbol

According to the CCFI value (=3), the separator 304 specifies from the fourth OFDM symbol #4 that a data symbol is allocated. The thus-specified data symbol is output to the demodulator 305. In the example shown in FIG. 4, the fourth OFDM symbol #4 corresponds to the data symbol D_11, and the fifth OFDM symbol #5 corresponds to the data symbol D_10. Likewise, the sixth to final fourteenth OFDM symbols #6 to #14 sequentially correspond to the data symbols D_9 to D_1.

(B2) Demodulation Processing

The demodulator 305 demodulates the data symbols D_11 to D_1 in sequence in which the symbols are input by the separator 304, by means of a previously-reported modulation multivalued number, to thus generate demodulated information; and outputs the demodulated information to the receiving Circular Buffer 306.

(B3) Processing for storing data in the receiving Circular Buffer

The receiving Circular Buffer 306 re-arranges demodulated information (demodulated data symbols) from its end to top in a reverse order and stores the thus-rearranged information as D_1 to D_11 as the locations where predetermined data are stored, in an area that extends from the starting point indicated by a previously-notified RV parameter and is equal in size to received data.

Through foregoing processing, D_1 to D_4 among the demodulated information D_1 to D_11 are allocated to locations corresponding to systematic bits (the interleaved S in a bottom row of FIG. 4) of the encode word in the receiving Circular Buffer 306, and D_5 to D_11 are stored at locations corresponding to parity bits (the interleaved and interlaced P1 and P2 in the bottom row of FIG. 4) of the encode word in the receiving Circular Buffer 306. Therefore, storage gap does not arise in the receiving Circular Buffer. In this case, the data symbols that have been separated from the control information and demodulated from the OFDM symbols are reconstructed and allocated by the receiving Circular Buffer while arranged in an order reverse to the order along which the received OFDM symbols are arranged; namely, while arranged in the same order as that in which the encode word data are allocated in the original transmission Circular buffer. In the example, the received data symbol D_12 is lost by the receiving station by means of erroneous recognition of an CCFI value. As a result of the data being lost by the receiving end, the encoding gain slightly become smaller; however, a receiving failure, which would otherwise be caused by gap of storage data in the receiving Circular Buffer or loss of first data, does not arise.

As mentioned above, according to the present embodiment, when the receiving station is a Persistent-UE to which Persistent-scheduling is applied, when the number of OFDM symbols to which the control channels CCH are applied is recognized by making a reference to a CCFI, and when there is performed operation for specifying data symbols and storing the data symbols in a Circular Buffer, it is possible to prevent occurrence of a packet failure, which would otherwise arise during first receiving operation for reasons of erroneous storage of data, even if a CCFI error has arisen in the receiving station. Thus, it is possible to prevent data from being synthesized while deviated during retransmission.

The present embodiment corresponds to simple processing for reading data from the transmission Circular Buffer and storing data into the receiving Circular Buffer in an order reverse to the order in which data are originally arranged. Therefore, the steps and the configuration involved in processing can be simplified. Moreover, the transmission Circular Buffer and the receiving Circular Buffer can hold data continuity and perform continuous processing during transmission and receiving operations. Consequently, it is possible to avoid occurrence of a change in the read order of the transmission Circular Buffer and the storage order of the receiving Circular Buffer, which would otherwise be caused by a CCFI value, and avoid intermittent allocation of data, which would otherwise be caused by allocating data to a plurality of receiving stations, so that complication of processing conforming to various conditions can be inhibited.

### Second Embodiment

A second embodiment shows an example case where a unit for one transmission (Transport-block) includes a plurality of encoding units (Code-blocks). In the present embodiment, when one Transport-block includes a plurality of Code-blocks, all sets of Code-block data are arranged so as to be uniformly allocated to respective OFDM symbols.

A transmission station and a receiving station of the second embodiment are analogous to their counterparts of the first embodiment shown in FIGS. 1 and 3 in terms of a block configuration. The second embodiment differs from the first embodiment in connection with reading processing of the transmission Circular Buffer 103 shown in FIG. 1 and processing for storing data into the receiving Circular Buffer 306 shown in FIG. 3. Descriptions are hereunder provided by providing a specific example.

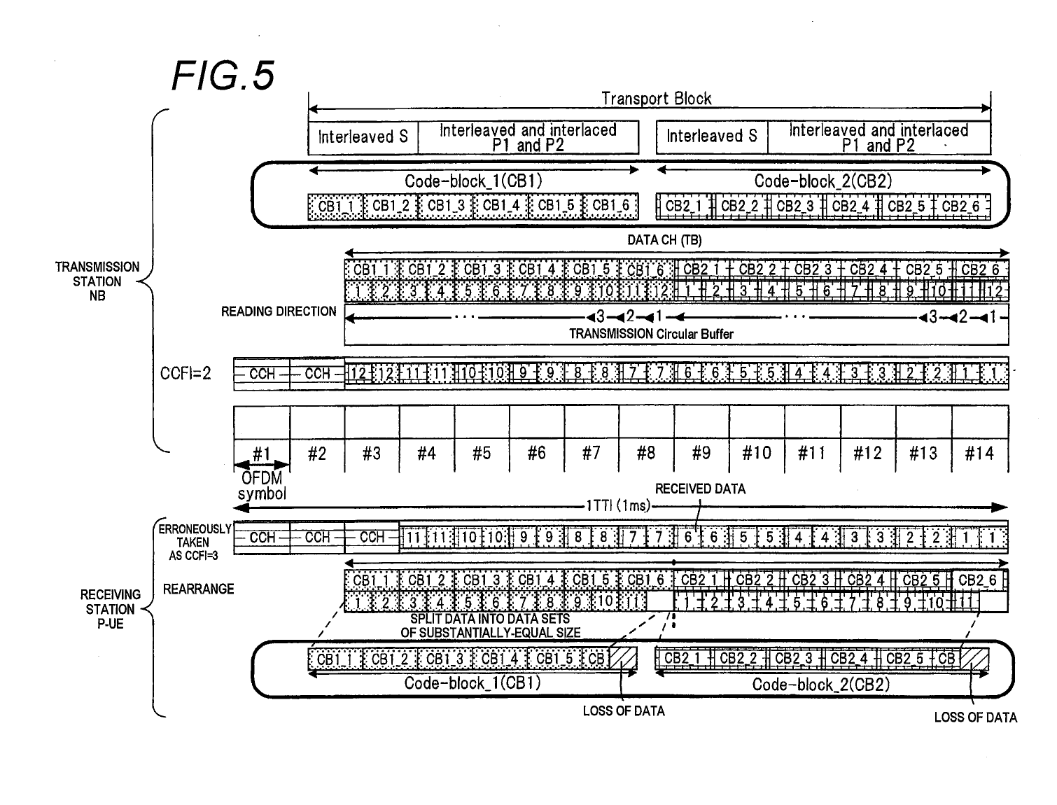

FIG. 5 shows exemplary data processing and an exemplary allocation configuration of data of the second embodiment. As is the case with the first embodiment, FIG. 5 shows a case where a transmission station is radio communication base station equipment NB and where a receiving station is radio communication mobile station equipment P-UE that is Persistent-UE. In this embodiment, one Transport-block includes two Code-blocks, and each of Code block_1 (CB1) and Code-block_2 (CB2) includes modulated data symbols 1 through 12. Specifically, the Code-block_1 (CB1) has data symbols 1 through 12 in CB1_1 to CB1_6, and the Code-block_2 (CB2) has data symbols 1 through 12 in CB2_1 to CB2_6. When the data size of one Transport-block surpasses the upper limit of the Code-block, processing is performed by dividing the Transport-block into a plurality of Code-blocks.

First, read processing of the transmission Circular Buffer 103 of the second embodiment is described. Explanations are here provided for a case where the receiving station receives the information, which has been transmitted by the transmission station at CCFI=2, erroneously as CCFI=3.

The transmission Circular Buffer 103 specifies encode word data to be transmitted, in accordance with an RV parameter and the size of transmission data provided by the controller 112. Encode word data pertaining to the thus-specified, respective Code-blocks from their end to top are sequentially read in a reverse order, and the thus-read data are output to the modulator 104. The encode word data are uniformly read at that time in a time domain in such a way that encode word data pertaining to Code-block_1 and Code-block_2 become uniform with respect to the respective OFDM symbols. After the thus-read encode word data have been modulated by the modulator 104, the multiplexer 105 allocates the data symbols in such a way that two Code-blocks are uniformly allocated to each of the OFDM symbols. Data symbols of two Code-blocks are uniformly arranged in the time domain with respect to each of the OFDM symbols while arranged in an order opposite to the order in which encode word data in the transmission Circular Buffer are originally arranged.

Processing for storing data into the receiving Circular Buffer 306 in the second embodiment will now be described. The separator 304 specifies and separates data symbols in accordance with a CCFI value, and the demodulator 305 demodulates the data symbols, to thus generate demodulated information.

From the starting point indicated by the previously-notified RV parameter, the receiving Circular Buffer 306 re-arranges the demodulated information in reverse order from its end to top on a per-Code-block basis, and stores the thus-rearranged information. Demodulated information about Code-block_1 and Code-block_2 uniformly arranged along the time domain is split into two pieces of information; namely, Code-block_1 information and Code-block_2 information which are of substantially the same size, and the thus-split pieces of information are stored. As a result, the respective Code-blocks are recovered and arranged in the receiving Circular Buffer 306 while arranged in an order reverse to the order in which the received OFDM symbols are arranged; namely, while arranged in the same order as that in which encode word data are originally arranged in the transmission Circular Buffer at the transmission side.

In an example shown in FIG. 5, a received data symbol 12 of each of the Code-blocks is lost as a result of the receiving station having erroneously recognized the CCFI value. An encode gain is slightly made smaller as a result of loss of data at an end position, but gap of storage of data in the receiving Circular Buffer and erroneous receiving operation resulting from loss of first data do not arise in all of the Code-blocks.

Thus, according to the embodiment, in a case where one Transport-block includes a plurality of Code-blocks, even when the Persistent-UE of the receiving station has caused a CCFI error, packet errors of subsequent Code-blocks, which would otherwise be caused by erroneous storage of data, can be prevented, and it is possible to prevent data from being synthesized while deviated during retransmission.

### Third Embodiment

A third embodiment shows an example in which CCFI information about a TTI received during preceding transmission operation is incorporated into control information notified to the Persistent-UE during retransmission.

A transmission station and a receiving station of the third embodiment are analogous to their counterparts of the first embodiment shown in FIGS. 1 and 3 in terms of a block configuration. The third embodiment differs from the first embodiment in connection with control information in the controller 112 shown in FIG. 1. Descriptions are hereunder provided by providing a specific example.

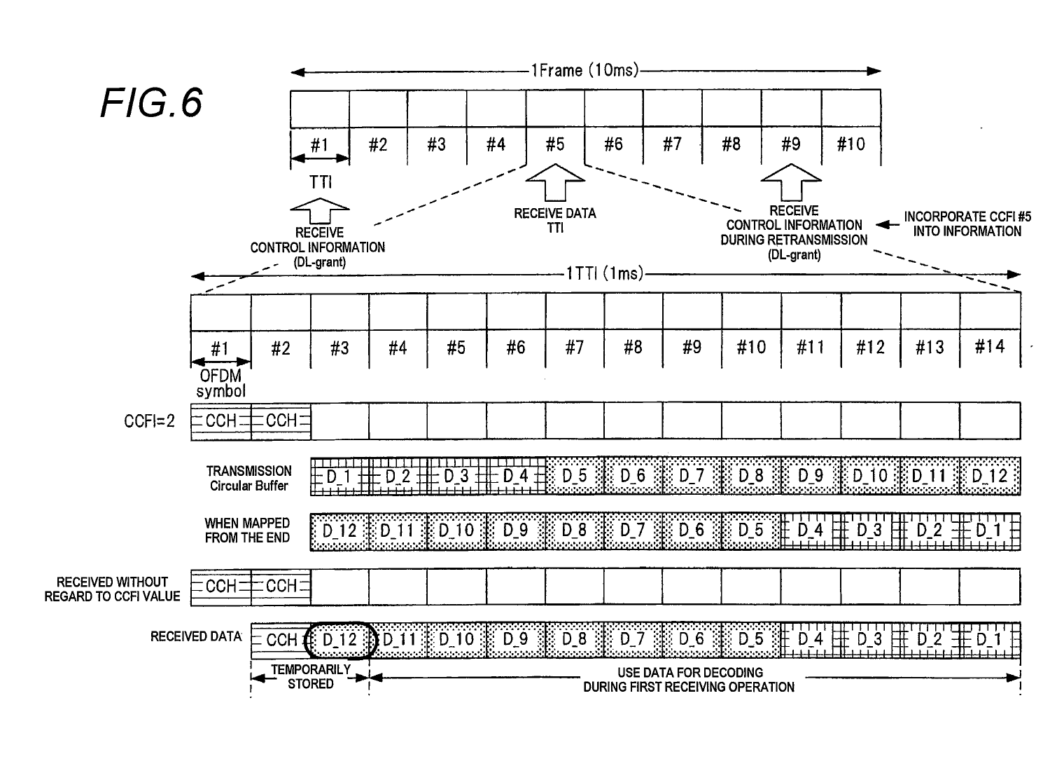

FIG. 6 shows exemplary data processing and an exemplary allocation configuration of data of the third embodiment. As is the case with the first embodiment, FIG. 6 shows a case where a transmission station is radio communication base station equipment NB and where a receiving station is radio communication mobile station equipment P-UE that is Persistent-UE.

In the present embodiment, when one frame (e.g., 10 ms) includes ten TTIs (e.g., one TTI=1 ms) #1 to #10, the receiving station of the Persistent-UE is assumed to receive control information (DL-grant) by means of the first TTI #1; receive data by means of the fifth TTI #5; and receive control information (DL-grant) during retransmission by means of the ninth TTI #9 when retransmission is performed. The present embodiment is assumed to be directed to processing from the first receiving operation to the first retransmission operation. The receiving station performs decoding operation by use of only the fourth to fifteenth OFDM symbols #4 to #14 during the first receiving operation regardless of the value of the CCFI. Specifically, only the OFDM symbols having no chance of being allocated control channels CCH regardless of a CCFI value are used for decoding.

In this case, when CCFI=2 is achieved, data D_12 are allocated to the third OFDM symbol #3 as received data. However, data pertaining to the second and third OFDM symbols #2 and #3 are only, temporarily stored during the first receiving operation without being used for decoding. As a result, recessive receiving operation, which would otherwise arise when a CCFI error for a smaller value has arisen; for instance, when CCFI=2 is erroneously recognized as CCFI=1, can be avoided.

In the third embodiment, the controller 112 of the transmission station causes control information (DL-grant), which is transmitted to the receiving station of the Persistent-UE at the time of retransmission, to include the CCFI information used in the first transmission operation. The receiving station acquires a CCFI value having a high degree of reliability by reference to CCFI information included in the retransmitted control information. As a result, the receiving station performs receiving operation for the case of retransmission by use of the CCFI information included in the retransmitted control information; can perform decoding by synthesizing the information (D_12 in the embodiment shown in FIG. 6) that has been uncertain during the first receiving operation; and hence can acquire an encoding gain.

As mentioned above, according to the embodiment, even when the Persistent-UE of the receiving station has caused a CCFI error, occurrence of excessive receiving operation can be prevented. Further, data that are uncertain during the first receiving operation can be synthesized and decoded from the retransmitted control information, and hence an encoding gain is obtained.

### Example Modifications

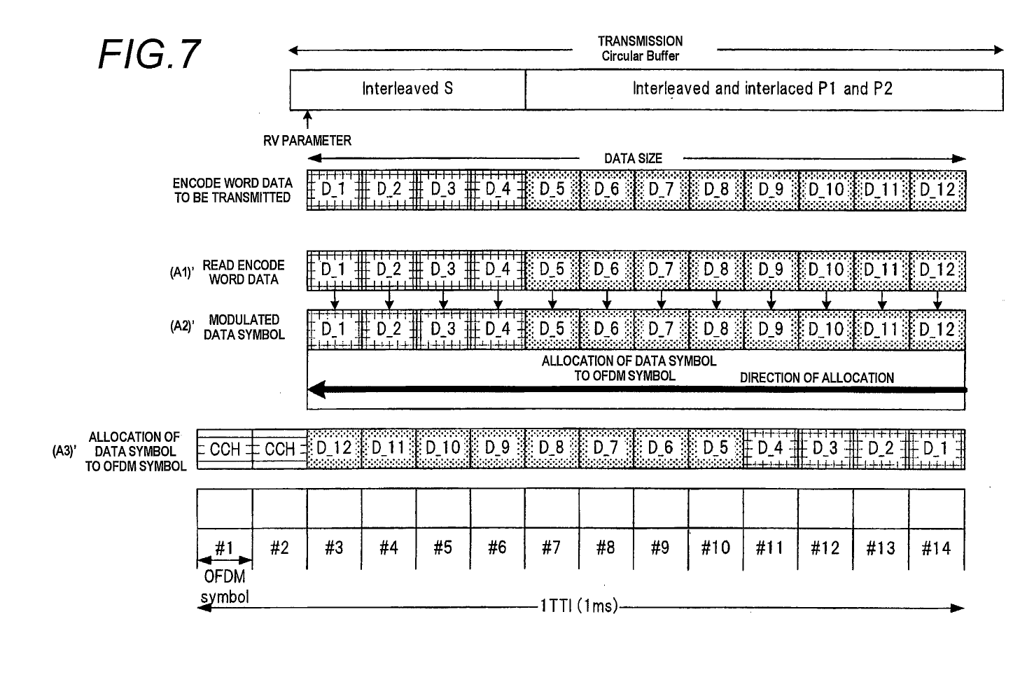

FIG. 7 shows exemplary data processing and an exemplary allocation configuration of data of a first example modification of the embodiments. An example in which read processing of the transmission Circular Buffer 103 and processing of the multiplexer 105 for allocating data symbols to OFDM symbols are changed is provided as a first example modification.

The embodiment has described the example in which reading processing of the transmission Circular Buffer 103 is performed in a reverse order. However, in the first example modification, read processing of the transmission Circular Buffer 103 is carried out in a forward order in place of the example. Further, the multiplexer 105 performs processing so as to allocate modified data symbols to the OFDM symbols in a reverse order from the OFDM symbol #14 at the end of the TTI. Processing for storing data into the receiving Circular Buffer 306 performed at the receiving end is the same as that described in connection with the first through third embodiments.

In the first example modification, for instance, processing (A1)′ to (A3)′ shown in FIG. 7 is performed in lieu of processing (A1) to (A3) shown in FIG. 2. In this case, encode word data D_1 to D_12 are read as they are in a forward order from the transmission Circular Buffer 103. After the encode word data have been modulated by the modulator 104, the multiplexer 105 allocates data symbols to the OFDM symbols in a reverse order from the fourteenth OFDM symbol #14 to the third OFDM symbol #3. As a result, the data symbols are sequentially allocated to OFDM symbols in a reverse order, e.g., D_12, D_11, D_1.

An advantage similar to those yielded by the first through third embodiments is also yielded through processing of such a first example modification. Even when a CCFI error has arisen in the receiving station, occurrence of a packet error, which would otherwise arise in the first receiving operation for reasons of erroneous storage of data, can be prevented, and it is possible to prevent data from being synthesized during retransmission operation while deviated.

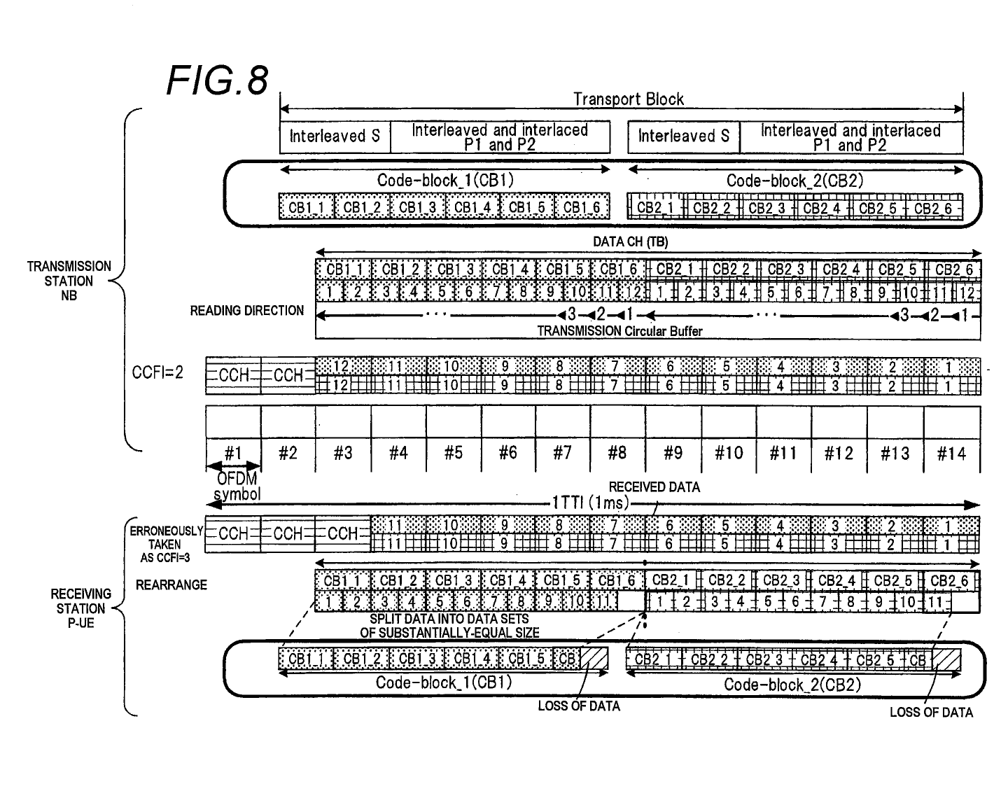

FIG. 8 shows exemplary data processing and an exemplary allocation configuration of data of a second example modification of the embodiment. An example in which a change is made to the allocation of the plurality of Code-blocks described in connection with the second embodiment is provided as a second example modification.

In the second embodiment, during read processing of the transmission Circular Buffer 103 and processing for storing data in a receiving circular buffer 306, Code-block data of respective Code-block_1 and Code-block_2 are allocated to respective OFDM symbols so as to become uniform in time domain. Meanwhile, in place of processing, all of the sets of Code-block data (two sets of Code-block data of Code-block_1 and Code-block_2 in the modification) are allocated to respective OFDM symbols in the second example modification, so as to become uniform in frequency domain.

An advantage similar to those yielded by the second embodiment is also yielded through processing of such a second example modification. Even when the Persistent-UE of the receiving station has caused a CCFI error, occurrence of a packet error, which would otherwise arise all of Code-blocks for reasons of erroneous storage of data, can be prevented, and it is possible to prevent data from being synthesized during retransmission operation while deviated.

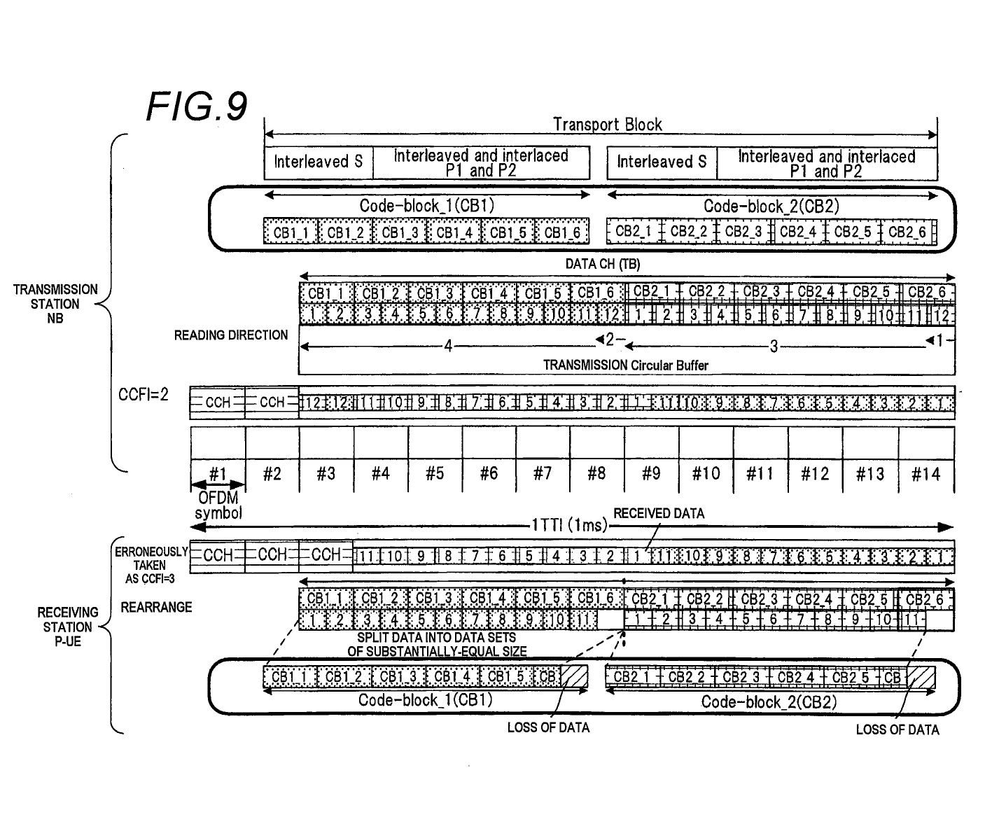

FIG. 9 shows exemplary data processing and an exemplary allocation configuration of data of a third example modification of the embodiment. Another example in which a change is made to the allocation of the plurality of Code-blocks described in connection with the second embodiment is provided as a third example modification.

In the second embodiment, during read processing of the transmission Circular Buffer 103 and processing for storing data in the receiving circular buffer 306, Code-blocks data of respective Code-block_1 and Code-block_2 are allocated to respective OFDM symbols so as to become uniform in time domain. Meanwhile, in place of the processing, all of the sets of Code-blocks data are uniformly allocated solely to OFDM symbols to which control channels CCH are possibly allocated in the third example modification. In the present example, two sets of Code-blocks data of Code-block_1 and Code-block_2 are allocated solely to the third OFDM symbol #3 to which a control channel CCH is possibly allocated, so as to become uniform in time domain.

An advantage similar to those yielded by the second embodiment is also yielded through processing of such a third example modification. Even when the Persistent-UE of the receiving station has caused a CCFI error, occurrence of a packet error, which would otherwise arise in all of Code-blocks for reasons of erroneous storage of data, can be prevented, and it is possible to prevent data from being synthesized during retransmission operation while deviated.

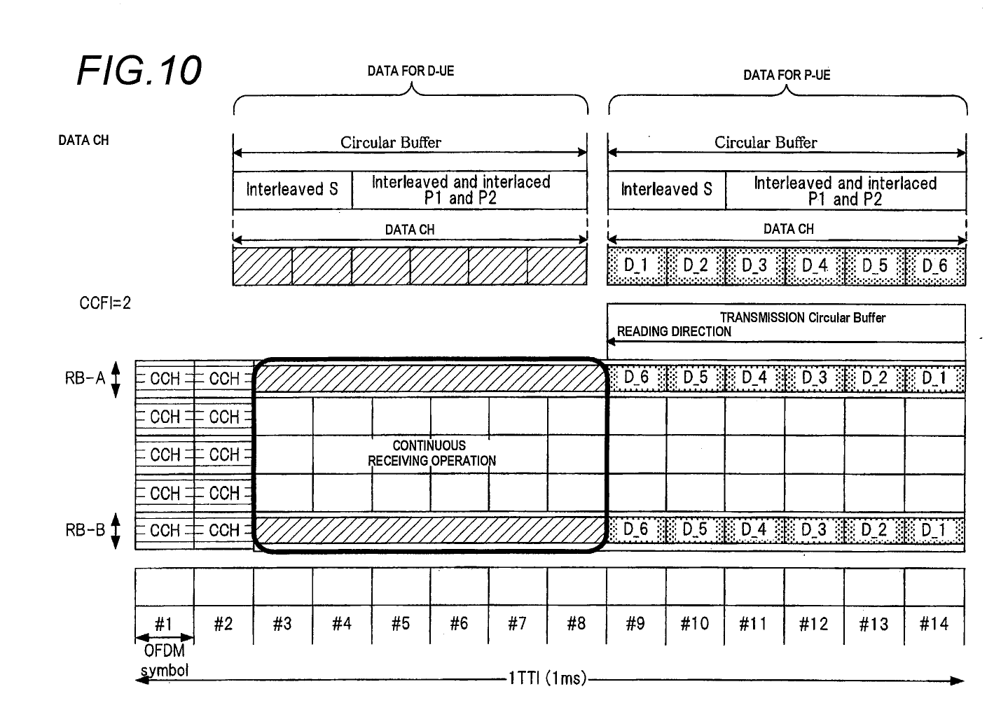

FIG. 10 shows exemplary data processing and an exemplary allocation configuration of data of a fourth example modification of the embodiment. As in the fourth example modification, the first through third embodiments can also be applied to (distributed allocation) a case where Dynamic-UE to which Dynamic-scheduling is applied and Persistent-UE to which Persistent-scheduling is applied are allocated into one TTI in a multiplexed manner.

When data for use in Dynamic-UE and data for use in Persistent-UE are multiplexed, the transmission station allocates data channels for use in the Persistent-UE in a reverse order from the OFDM symbol at the end of a TTI. In this modification, encoded data D_1 through D_6 for use in Persistent-UE are read in a reverse order, e.g., D_6 to D_1, from the end of the transmission Circular Buffer, and the data symbols D_6 to D_1 are allocated to the ninth to fourteenth OFDM symbols #9 to #14 on the end side of the OFDM symbols. The receiving station of Persistent-UE inversely rearranges the reversely-arranged data into original order and stores the thus-rearranged data into the receiving Circular Buffer.

Even in the fourth example modification, data continuity can be held as in the embodiments, and it is possible to avoid intermittent allocation of data in each of the receiving stations when a plurality of receiving stations are allocated data. As a result of the data channels of Persistent-UE being reversely allocated to OFDM symbols from the OFDM symbol at the end of a TTI, an allocation area of Dynamic-UE for Distributed allocation can be made continuous timewise. Since continuous receiving can be performed without regard to a CCFI value, receiving operation can simply be performed.

The CCFI utilized for descriptions in the present invention are sometimes expressed as a “PCFICH (Physical Control Format Indicator Channel).”

The present invention is not limited to the radio communication apparatuses described in connection with the embodiments and is scheduled to be liable to modifications or applications made by the skilled artisans in accordance with the descriptions of the present patent specification and the well-known techniques, and those modifications and applications shall fall within a range where protection is sought.

In the first embodiment (FIG. 2), reversely-arranged data (D_12 to D_1) are allocated to the OFDM symbols #3 to #14. However, there may also be adopted a configuration by means of which only data symbols consisting solely of parity bits are mapped to an OFDM symbol (#3) to which control channels CCH are possibly allocated such as D_11, 9, 6, 5, 7, 8, 12, 10, 2, 3, 4, 1 (while an allocation pattern is shared between transmission and receiving times).

The embodiments of the present invention have described the examples in which turbo encoding is used for error correction encoding. However, LDPC encoding may also be employed.

The first embodiment (FIG. 4) shows the example in which D_12 are allocated to the OFDM symbol #3 where data received with a CCFI error are lost. However, there may also be adopted a method for allocating parity bits that are less likely to cause performance deterioration (or prevent shortening of the minimum humming distance between encode words).

In the respective embodiments, the present invention has been described by means of taking, as an example, a case where the present invention is configured by means of hardware. However, the present invention can also be implemented by means of software.

The respective functional blocks used in description of the respective embodiments are realized by means of an LSI that is typically an integrated circuit. The functional blocks may also be packaged into a single chip individually. Alternatively, the functional blocks may also be embodied by a single chip so as to encompass some or all of the functional blocks. Although the chip is herein mentioned as an LSI, the chip may often be called an IC, a system LSI, a super LSI, or an ultra LSI according to the degree of integration.

A technique for implementing the functional blocks into an integrated circuit is not limited to the LSI, and the functional blocks may also be realized by means of a custom-designed circuit or a general-purpose processor. An FPGA (Field Programmable Gate Array) that can be programmed after manufacture of an LSI or a reconfigurable processor that allows reconfiguration of connections or settings of circuit cells in an LSI may also be utilized.

Moreover, if a technique for realizing an integrated circuit in place of an LSI emerges by virtue of a progress in semiconductor technique or another technique derived from the semiconductor technique, it is natural that the functional blocks may also be integrated by use of the technique. An adaptation of biotechnology can said to be potentially possible.

The present invention has been explained in detail with reference to the particular embodiments. However, it is obvious for those skilled in the art that various variations and modifications can be applied without departing from the spirit and the scope of the present invention.

This application is based upon and claims the benefit of priority of Japanese Patent Application No. 2007-208128 filed on Aug. 9, 2007, the contents of which are incorporated herein by reference in its entirety.

### INDUSTRIAL APPLICABILITY

The present invention yields an advantage of being able to prevent occurrence of a packet error, which would otherwise arise during first receiving operation because of erroneous storage of data in a buffer even when a CCFI error has arisen and that can prevent data from being synthesized while deviated during retransmission. The present invention is useful for use in a radio communication apparatus, a radio communication system, a radio communication method, and the like; for instance, radio communication base station equipment and radio communication mobile station equipment in a cellular system that perform data transfer using an OFDM.

1. A radio communication apparatus that serves as a transmission station for transmitting data using OFDM (Orthogonal Frequency Division Multiplexing) to a receiving station to which Persistent-scheduling is applied, the radio communication apparatus comprising:
a Circular Buffer for storing data to be transmitted to the receiving station; and
a transmission data processor that processes data to be transmitted to the receiving station to which Persistent-scheduling is applied, in reverse order in either processing for reading data from the Circular Buffer or processing for allocating modulated data symbols to OFDM symbols.

2. The radio communication apparatus according to claim 1,
wherein the transmission data processor reads in reverse order data to be transmitted from an end of the data during processing for reading data from the Circular Buffer.

3. The radio communication apparatus according to claim 1,
wherein the transmission data processor allocates data in reverse order from an end of OFDM symbols during processing for allocating modulated data symbols to OFDM symbols.

4. The radio communication apparatus according to claim 1,
wherein, when one Transport-block to be transmitted to the receiving station contains a plurality of Code-blocks, the transmission data processor uniformly allocates all sets of Code-blocks data to respective OFDM symbols.

5. The radio communication apparatus according to claim 4,
wherein the transmission data processor allocates all sets of Code-blocks data to respective OFDM symbols so as to become uniform in time domain.

6. The radio communication apparatus according to claim 4,
wherein the transmission data processor allocates all sets of Code-blocks data to respective OFDM symbols so as to become uniform in a frequency domain.

7. The radio communication apparatus according to claim 4,
wherein the transmission data processor allocates all sets of Code-blocks data so as to become uniform solely to OFDM symbols to which a control channel is possibly allocated.

8. The radio communication apparatus according to claim 1,
wherein, when a first receiving station to which Dynamic-scheduling is applied and a second receiving station to which Persistent-scheduling is applied are multiplexed in a distributed manner as receiving stations that are objects of transmission from the transmission station, the transmission data processor allocates data to be transmitted to the second receiving station to which Persistent-scheduling is applied, in reverse order from an end of OFDM symbols in a transmission period.

9. The radio communication apparatus according to claim 1, further comprising a control information processor that incorporates a CCFI (Control Channel Format Indicator) information accepted during previous receiving operation, into control information to be notified when data are retransmitted to the receiving station to which Persistent-scheduling is applied.

10. A radio communication apparatus that serves as a receiving station to which Persistent-scheduling is applied and that performs data transmission with a transmission station by use of OFDM (Orthogonal Frequency Division Multiplexing), the radio communication apparatus comprising:
a Circular Buffer for storing data transmitted by the transmission station; and
a received data processor that, when received from the transmission station data allocated to OFDM symbols in reverse order, rearranges the data in reverse order and stores the rearranged data in predetermined data storage positions during processing for storing data into the Circular Buffer.

11. The radio communication apparatus according to claim 10,
wherein, when one Transport-block to be transmitted by the transmission station contains a plurality of Code-blocks, the received data processor rearranges and stores inversely-allocated data on a per-Code-block basis in a reverse order such that all sets of Code-blocks data become uniform with respect to respective OFDM symbols.

12. The radio communication apparatus according to claim 10,
wherein, when another receiving station to which Dynamic-scheduling is applied and the own receiving station to which Persistent-scheduling is applied are multiplexed in a distributed manner as receiving stations that are objects of transmission from a transmission station, the received data processor rearranges in reverse order into original positions data allocated in reverse order from an end of OFDM symbols of the own receiving station and stores the rearranged data.

13. A radio communication system for transmitting data using OFDM (Orthogonal Frequency Division Multiplexing) between a transmission station and a receiving station to which Persistent-scheduling is applied, the radio communication system comprising:
a first radio communication apparatus that serves as a transmission station having:
a Circular Buffer for storing data to be transmitted to the receiving station; and
a transmission data processor that processes data to be transmitted to the receiving station to which Persistent-scheduling is applied, in reverse order in either processing for reading data from the Circular Buffer or processing for allocating modulated data symbols to OFDM symbols; and
a second radio communication apparatus that serves as a receiving station to which Persistent-scheduling is applied having:
a Circular Buffer for storing data transmitted by the transmission station; and
a received data processor that, when received data allocated in reverse order from the transmission station, stores the data in reverse order in predetermined data storage positions during processing for storing data into the Circular Buffer.

14. A radio communication method for a radio communication apparatus that serves as a transmission station for transmitting data using OFDM (Orthogonal Frequency Division Multiplexing) to a receiving station to which Persistent-scheduling is applied, the method comprising:
a transmission data processing step of processing data to be transmitted to the receiving station to which Persistent-scheduling is applied, in reverse order in either processing for reading data from a Circular Buffer that stores data to be transmitted to the receiving station or processing for allocating modulated data symbols to OFDM symbols.

15. A radio communication method for a radio communication apparatus that serves as a receiving station to which Persistent-scheduling is applied and that performs data transmission with a transmission station by use of OFDM (Orthogonal Frequency Division Multiplexing), the method comprising:
a received data processing step of, when received data allocated in reverse order from the transmission station, storing the data in reverse order in predetermined data storage positions during processing for storing data into a Circular Buffer that stores data received from the transmission station.
